(19) United States
(12) Patent Application Publication
(10) Pub. No.: US 2020/0136073 A1
(43) Pub. Date: Apr. 30, 2020

(54) OPTOELECTRONIC DEVICES BASED ON HALIDE PEROVSKITES PASSIVATED WITH 2 DIMENSIONAL MATERIALS

(71) Applicant: KOREA INSTITUTE OF SCIENCE AND TECHNOLOGY, Seoul (KR)

(72) Inventors: In Soo KIM, Seoul (KR); Kwan Il LEE, Seoul (KR); Sang Bae LEE, Seoul (KR); Wonsuk LEE, Seoul (KR)

(21) Appl. No.: 16/386,264

(22) Filed: Apr. 17, 2019

(30) Foreign Application Priority Data
Oct. 29, 2018 (KR) 10-2018-0130158

(51) Int. Cl. H01L 51/44; H01L 51/42; H01L 51/00

(52) U.S. Cl. CPC H01L 51/448; H01L 51/4213; H01L 51/006; H01L 51/0047; H01L 51/0037

(57) ABSTRACT

Embodiments relate to an optoelectronic device including a substrate, a photoactive layer formed on the substrate to receive light and generate an electron-hole pair, an electron transport layer and a hole transport layer formed on both surfaces of the photoactive layer, a first electrode formed between the substrate and the photoactive layer, and a passivation layer formed at an opposite side to the first electrode on the photoactive layer.

### CROSS-REFERENCE TO RELATED APPLICATION

This application claims priority to Korean Patent Application No. 10-2018-0130158, filed on Oct. 29, 2018, and all the benefits accruing therefrom under 35 U.S.C. § 119, the contents of which in its entirety are herein incorporated by reference.

### BACKGROUND

### 1. Field

The present disclosure relates to optoelectronic devices, and more particularly, to optoelectronic devices based on halide perovskites passivated using 2-dimensional materials (for example, graphene and graphene oxide) having excellent barrier/anti-diffusion performance as well as optical, electrical and mechanical properties and a method of manufacturing the same.

### 2. Description of the Related Art

FIG. 1 is a diagram illustrating a crystal structure of a halide perovskite compound.

In general, a perovskite compound refers to a compound having the same crystal structure as the structure of CaTiO₃. This crystal structure is referred to as a perovskite structure, and generally has an ABX₃ structure as shown in FIG. 1. Here, A and B are cations, and X is an anion that bonds to them. The A cation bonds to twelve X anions, forming an AX₁₂ cuboctahedral structure, and the B cation bonds to six anions with a BX₆ octahedral structure. Particularly, when the perovskite compound includes at least one or two or more different types of halide anions (for example, including —F, —Cl, —Br and —I), it may be referred to as a halide perovskite compound.

Halide perovskite compounds can be synthesized using low cost raw materials and deposition processes highly compatible with existing semiconductor processes. Additionally, due to its excellent optical/electrical properties, halide perovskite compounds have gained much attention for application in next-generation optoelectronic devices (solar cells, light-emitting diodes, and photo-detectors).

However, upon exposure to moisture or heat (for example, heat exceeding 150° C.), halide perovskite compounds decompose into PbI₂ and no longer exhibit the qualities of a photoactive material. In an example, when the halide perovskite compound is CH₃NH₃PbI₃(s), a detailed decomposition process of each case is as follows: 1) moisture: CH₃NH₃PbI₃(s)→PbI₂(s)+CH₃NH₃I(aq), 2) heat: CH₃NH₃PbI₃(s)→PbI₂(s)+CH₃NH₂↑+HI↑

Accordingly, for commercialization of halide perovskite based optoelectronic devices, it is essential to improve stability of the material itself or on the device scale or halide perovskite based optoelectronic devices will not operate as optoelectronic devices, otherwise.

Passivation is a useful technique for protecting a material from moisture and/or heat. Because halide perovskite compounds are prone to degradation against moisture, heat, and chemicals, it is impossible to form a passivation layer directly on top of halide perovskite compounds by commonly used vacuum deposition methods.

On the other hand, bulk encapsulation technique is an indirect approach to passivating halide perovskite compounds. When bulk encapsulation is applied to an optoelectronic device, stability of the optoelectronic device is improved. However, while the bulk encapsulation technique protects the halide perovskite compound from moisture, it does not prevent egress of organic ions from the halide perovskite compound when exposed to heat.

### RELATED LITERATURES

### Patent Literatures

(Patent Literature 1) Korean Patent Publication No. 10-2016-0139986

### SUMMARY

According to an embodiment of the present disclosure, passivation of an optoelectronic device based on halide perovskite can be achieved using a 2-dimensional material (for example, graphene and graphene oxide) having excellent barrier/anti-diffusion performance as well as optical, electrical and mechanical properties is provided.

An optoelectronic device according to an aspect of the present disclosure may include a substrate, a photoactive layer formed on the substrate to receive light and generate an electron-hole pair, an electron transport layer and a hole transport layer formed on both surfaces of the photoactive layer, a first electrode formed between the substrate and the photoactive layer, and a passivation layer formed at an opposite side to the first electrode on the photoactive layer.

In an embodiment, the passivation layer may be made of a 2-dimensional material, and may be configured to capture a type of charge of the hole-electron pair generated in the photoactive layer.

In an embodiment, the optoelectronic device may include a first electrode formed on the substrate to capture an electron, an electron transport layer formed on the first electrode, a photoactive layer formed on the electron transport layer, a hole transport layer formed on the photoactive layer, and a passivation layer formed on the hole transport layer. Here, the passivation layer is made of a 2-dimensional material.

In an embodiment, the passivation layer may be made of a material including graphene.

In an embodiment, the passivation layer may be configured to capture the hole of the electron-hole pair generated in the photoactive layer through the hole transport layer.

In an embodiment, the passivation layer may act as a second electrode of the optoelectronic device.

In an embodiment, the optoelectronic device may include a first electrode formed on the substrate to capture an electron, an electron transport layer formed on the first electrode, a photoactive layer formed on the electron transport layer, a hole transport layer formed on the photoactive layer, a passivation layer formed on the hole transport layer, and a third electrode formed on the passivation layer. Here, the passivation layer is made of a 2-dimensional material and the third electrode may be made of metal.

In an embodiment, the passivation layer may be made of a material including graphene oxide.

In an embodiment, the passivation layer may receive a hole generated in the photoactive layer through the hole transport layer, and transport the hole to the third electrode.

In an embodiment, the metal of the third electrode may have a higher work function than a work function of graphene oxide.

In an embodiment, the graphene oxide of the passivation layer may be formed by ozone cleaning or oxygen plasma treatment.

In an embodiment, the photoactive layer may be made of a material including halide perovskite compounds.

In an embodiment, the first electrode may be made of a material selected from the group consisting of indium tin oxide (ITO), fluorine doped tin oxide (FTO), tin oxide, zinc oxide and their combinations.

In an embodiment, the hole transport layer may be made of a material including spiro-MeoTAD.

In an embodiment, the electron transport layer may be made of a material selected from the group comprising TiO₂, ZnO, SnO₂, PC₆₁BM, and their combinations.

In an embodiment, the optoelectronic device may include a second electrode formed on the substrate to capture a hole, a hole transport layer formed on the second electrode, a photoactive layer formed on the hole transport layer, an electron transport layer formed on the photoactive layer, and a passivation layer formed on the electron transport layer. Here, the passivation layer is made of a 2-dimensional material.

In an embodiment, the passivation layer may act as a first electrode of the optoelectronic device to capture an electron of an electron-hole pair generated in the photoactive layer through the electron transport layer.

In an embodiment, the hole transport layer may be made of a material including NiOx or PEDOT:PSS.

In an embodiment, the electron transport layer may be made of a material including a fullerene derivative having a lower conduction band of the photoactive layer than a conduction band of a perovskite solar cell.

In an embodiment, the electron transport layer may be made of a material including PC₆₁BM ([6,6] phenyl-C61-butyric acid methyl ester).

The optoelectronic device according to the above-embodiments may be a solar cell, a photodetector or a light emitting diode.

The halide perovskite based optoelectronic device according to an embodiment of the present disclosure may passivate the halide perovskite based photoactive layer using graphene which exhibits excellent barrier/anti-diffusion performance as well as optical, electrical and mechanical properties. Accordingly, it is possible to greatly improve stability of the optoelectronic device including the halide perovskite photoactive layer to which graphene passivation is applied.

Particularly, graphene based passivation is applied directly on the photoactive layer made of a halide perovskite material, which prevents egress of organic ions from the halide perovskite.

Additionally, the graphene based passivation layer may act as an electrode. As a result, the halide perovskite based optoelectronic device may be manufactured as a transparent optoelectronic device.

The effects of the present disclosure are not limited to the effects mentioned above, and other effects not mentioned herein will be clearly understood by those skilled in the art from the appended claims.

### BRIEF DESCRIPTION OF THE DRAWINGS

To describe the technical solutions of the embodiments of the present disclosure or related art more clearly, drawings required for describing the embodiments will be briefly introduced below. It should be understood that the accompanying drawings are provided for illustration purposes only, but not intended to limit the embodiments of the specification. Additionally, the accompanying drawings may show some elements to which various modifications such as exaggeration and omission are applied for clarity of description.

FIG. 1 is a diagram illustrating crystal structure of halide perovskite compounds.

FIG. 2 is a diagram showing a device structure of a solar cell according to an embodiment of the present disclosure.

FIG. 3 is a diagram illustrating band alignment of the solar cell of FIG. 2 according to an embodiment of the present disclosure.

FIG. 4 is a schematic diagram illustrating a process of forming a passivation layer according to an embodiment of the present disclosure.

FIG. 5 is a diagram showing a device structure of a solar cell according to another embodiment of the present disclosure.

FIG. 6 is a diagram illustrating band alignment of the solar cell of FIG. 5 according to another embodiment of the present disclosure.

FIG. 7 is a diagram showing a device structure of a solar cell according to still another embodiment of the present disclosure.

FIG. 8 is a diagram illustrating band alignment of the solar cell of FIG. 7 according to still another embodiment of the present disclosure.

FIG. 9 is a schematic diagram illustrating a process of forming a passivation layer according to still another embodiment of the present disclosure.

### DETAILED DESCRIPTION

The terminology used herein is for the purpose of describing particular embodiments only, but not to be considered limiting the scope of the present disclosure. The singular forms as used in the detailed description and the appended claims of the present disclosure are intended to include the plural forms as well, unless the context clearly indicates otherwise. Additionally, it should be understood that the term “and/or” as used herein includes any or all possible combinations of at least one relevant enumerated item.

The terms “first”, “second”, and the like are used to describe various parts, components, areas, layers and/or sections, but are not limited thereto. These terms are only used to distinguish one part, component, area, layer or section from another. Accordingly, a first part, component, region, layer or section stated below may be referred to as a second part, component, region, layer or section without departing from the scope of the present disclosure.

If an element is referred to as being “above” another element, it can be directly above the other element or intervening elements may be present. In contrast, if an element is referred to as being “directly above” another element, there are no intervening elements present.

Spatially relative terms (e.g., “beneath”, “below”, “above” and the like) may be used herein for ease of description in describing a relationship between one element and another as illustrated in the figures. These terms are intended to encompass the intended meaning in the figures as well as different meanings or operations of the device in use. For example, if the device in the figures is turned over, elements described as “below” or “beneath” other elements would then be oriented “above” the other elements. Thus, the term “below” can encompass both an orientation that is above, as well as, below. The device may otherwise rotate (90° or at any other angle) and the spatially relative terms should be interpreted accordingly.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the specification, an optoelectronic device is a device that converts light energy to electrical energy and vice versa using the properties of semiconductor when it receives light (for example, sunlight) or electrical bias (for example, current), and includes a LED (light emitting diode) and related devices (e.g., an LED chip, LED lighting device (an LED street light and an LED tube light), an intermediate infrared LED), a photodetector, an optical fiber lighting system, a home solar cell, a solar cell for electricity generation, a CCD and a CMOS. Hereinafter, the present disclosure is described based on a solar cell for clarity of description, but it will be obvious to those skilled in the art that the present disclosure is understood as being not limited to a solar cell.

An optoelectronic device according to embodiments of the present disclosure includes a substrate, a photoactive layer formed on the substrate to receive light and generate an electron-hole pair, two electrode as charge capture layers (an electron capture layer and a hole capture layer) formed on either electron transport layer or hole transport layer to capture charge, and two charge transport layers (an electron transport layer and a hole transport layer) to transfer charge to each charge capture layer. One of the charge capture layers further acts as a passivation layer to protect the internal components of the optoelectronic device from the outside.

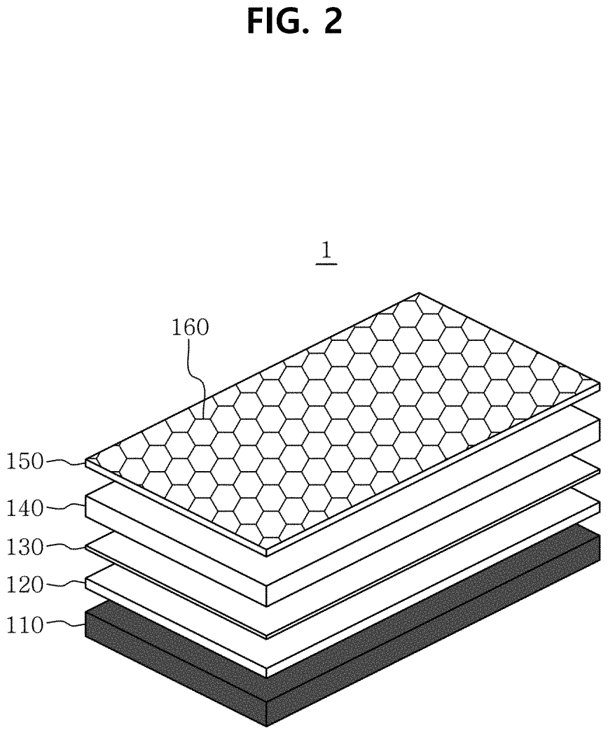

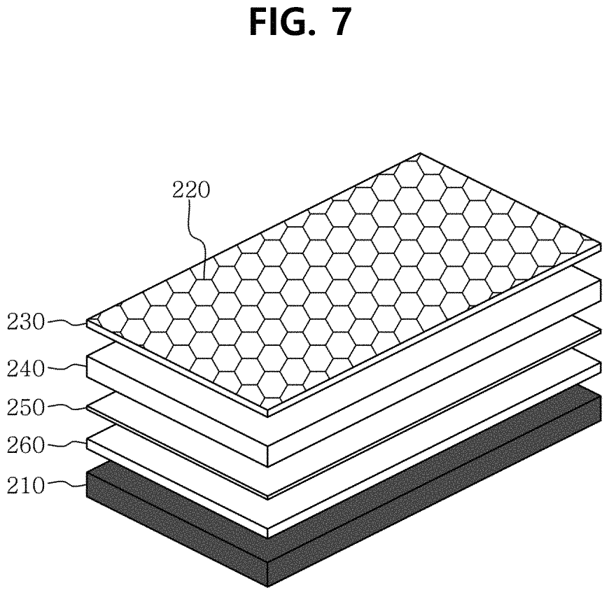

The internal structure of the optoelectronic device may be a forward structure (N-I-P structure) and an inverted structure (P-I-N structure) according to the physical properties of the components of each layer. This is described in more detail with reference to FIGS. 2 and 7 below.

Hereinafter, the embodiments of the present disclosure are described in detail with reference to the accompanying drawings.

### First Embodiment

FIG. 2 is a diagram showing a device structure of a solar cell according to an embodiment of the present disclosure.

Referring to FIG. 2, the solar cell 1 includes an electron electrode 120 formed on a substrate 110 to capture an electron, an electron transport layer 130 formed on the electrode 120, a photoactive layer 140 formed on the electron transport layer 130, a hole transport layer 150 formed on the photoactive layer 140, and a passivation layer 160 formed on the hole transport layer 150. The passivation layer 160 further acts as a hole electrode to capture a hole. The passivation layer 160 serving as the hole electrode will be described in more detail below.

In an embodiment, the photoactive layer 140 may be made of a material including a halide perovskite compound.

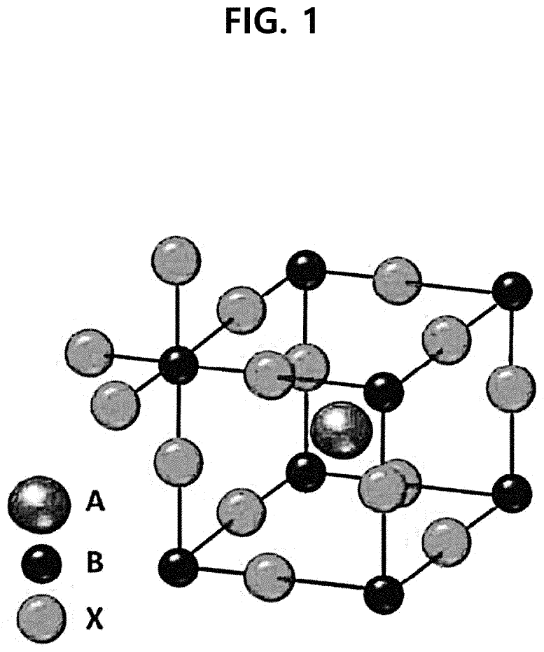

The halide perovskite compound refers to a compound having a crystal structure of ABX₃ as shown in FIG. 1. Here, A and B are cations, and X is an anion that bonds to them. For example, the A cation bonds to twelve X anions, forming an AX₁₂ cuboctahedral structure, and the B cation bonds to six anions, forming a BX₆ octahedral structure.

When the perovskite compound includes at least one or two or more different types of halide anions (for example, including —F, —Cl, —Br and —I), it may be referred to as a halide perovskite compound.

The halide perovskite compound may include an organic cation at the position of the A cation. In an embodiment, the organic cation may include one selected from the group comprising C1-20 alkyl group, C1-20 alkyl group replaced by amine group and alkali metal, or combinations of two or more of them. Here, the alkali metal may include Li, Na, K, Rb, Cs and Fs.

The halide perovskite compound may include a metal cation at the position of the B cation. In an embodiment, the metal cation includes Pb, Sn, Ti, Nb, Zr and Ce.

As such, the halide perovskite compound may be an organic/inorganic composite material of 3-dimensional structure, for example, including CH₃NH₃⁺, NC(NH₂)₂+. The halide perovskite compound has the band gap energy of about 1.5 eV (CH₃NH₃PbI₃) to 2.3 eV (CH₃NH₃PbBr₃), and may act as a light-absorbing material of a solar cell.

The working principle of the halide perovskite based solar cell 1 according to an embodiment is described for illustration as follows: when sunlight is incident, photons are first absorbed in halide perovskite, the photoactive layer 140, and accordingly, electron transition (i.e., energy transition) occurs in the halide perovskite from a ground state to an excited state. The photoactive layer 140 generates an electron-hole pair by the electron transition, and the excited state electron is transported to the electrode 120 through the electron transport layer 130. When the electrode 120 is electrically connected to the passivation layer 160 through an external circuit, the electron may move to the passivation layer 160 through the external circuit. On the other hand, the hole generated in the photoactive layer 140 is captured in the passivation layer 160 through the hole transport layer 150. As a result, the solar cell 1 can work (generates current).

The substrate 110 is a component that supports the solar cell 1, and in an embodiment, the substrate 110 may be made of a glass or plastic material. The plastic material may include a material selected from the group comprising poly(ethylene terephthalate) (PET), poly(ethylene naphthalate) (PEN), polyimide (PI) and their combinations, but is not limited thereto.

Additionally, the substrate 110 is made of a transparent material. Here, “transparent” refers to a state in which most of visible rays pass through a material so that human retinal cells or other external devices hardly receive light that reflects from the material.

The electrode (a first electrode or an electron electrode) 120 acts as an electron capture layer to receive and capture the electron generated by sunlight through the electron transport layer 130.

The electrode 120 may be made of a material selected from the group consisting of indium tin oxide (ITO), fluorine doped tin oxide (FTO), tin oxide, zinc oxide and their combinations, but may not be limited thereto. In an embodiment, the electrode 120 is made of a material including FTO.

The electrode 120 is formed on the substrate 110. The electrode 120 may be formed on the substrate 110 by electroplating, sputtering and physical vapor deposition (PVD) such as electron beam evaporation, but is not limited thereto.

The electron transport layer 130 is configured to effectively transport the excited electron from the photoactive layer 140 to the electrode 120. In the solar cell, the photoactive layer 140 generally has a short electron movement distance. Thus, the exited electron may not reach the electrode 120. As the electron transport layer 130 made of a material having longer electron diffusion lengths may transport electrons to the electrode 120, the issue with diffusion lengths can be resolved.

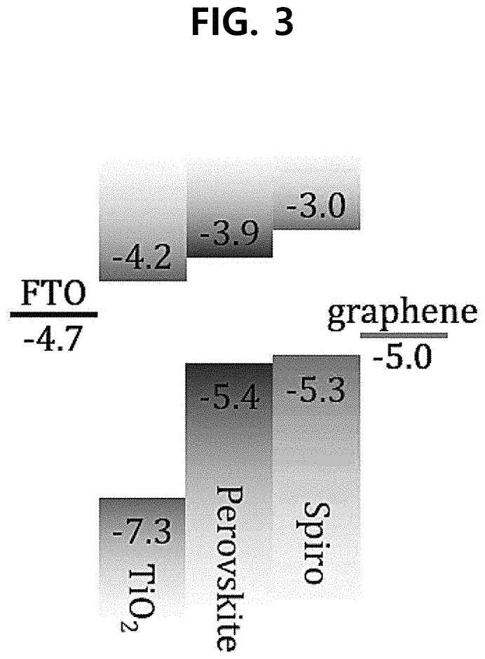

FIG. 3 is a diagram illustrating band alignment of the solar cell of FIG. 2 according to an embodiment of the present disclosure.

The electron transport layer 130 is formed from a material having a lower conduction band than the conduction band of the perovskite solar cell. In an embodiment, the electron transport layer 130 may be made of n-type semiconducting oxides and/or organic materials, such as TiO₂, ZnO, SnO₂, PC₆₁BM (Phenyl-C61-butyric acid methyl ester), and their combinations, but not limited to. For example, the electron transport layer 130 may be made of metal oxide such as (e.g., TiO₂ and/or ZnO).

Referring back to FIG. 2, as described above, the photoactive layer 140 formed on the electron transport layer 130 includes a halide perovskite compound which absorbs light (for example, sunlight) in order to generate electrical energy from light energy.

The hole transport layer 150 is configured to effectively transport the excited hole in the photoactive layer 140 to the passivation/electrode layer 160. Accordingly, it is possible to overcome the limits of short hole diffusion lengths within the photoactive layer 140.

The hole transport layer 150 is formed from a material having a higher valence band than the valence band of the photoactive layer 140. In an embodiment, the hole transport layer 150 may be made of a material including spiro-MeOTAD, but is not limited thereto.

The hole transport layer 150 is formed on the photoactive layer 140. The hole transport layer 150 may be formed on the photoactive layer 140 by a spin coating process or a thermal evaporation process, but is not limited thereto.

The passivation layer 160 prevents decomposition of the photoactive layer 140 by preventing ingress of moisture into and egress of organic cations out of the photoactive layer upon exposure to moisture and/or heat. The passivation layer 160 may be made of a conductive 2-dimensional (2D) material that can prevent inward diffusion of moisture and outward diffusion of organic cations. In an embodiment, the 2D material that forms the passivation layer 160 may include graphene.

Graphene is an excellent thermal/chemical diffusion barrier. Additionally, because graphene has an atomic-scale thickness, and thus high light transmission, application of graphene in an optoelectronic device does not reduce absorption/emission efficiency. Additionally, in contrast to metal oxide based passivation, 2D materials such as graphene exhibit good mechanical properties, which allows for application in flexible electronics. Furthermore, electrical properties of 2D material such as graphene can be widely tuned, and thus may be used as an electrode as well as a charge transport layer.

As described above, the photoactive layer 140 made of the material including the halide perovskite compound generates an electron-hole pair therein when it receives sunlight. The electron generated in the photoactive layer 140 is transported to the electrode 120 through the electron transport layer 130. Additionally, the hole generated in the photoactive layer 140 is transported to the passivation layer 160 through the hole transport layer 150, and finally, is captured in graphene. As a result, the solar cell 1 generates electric current.

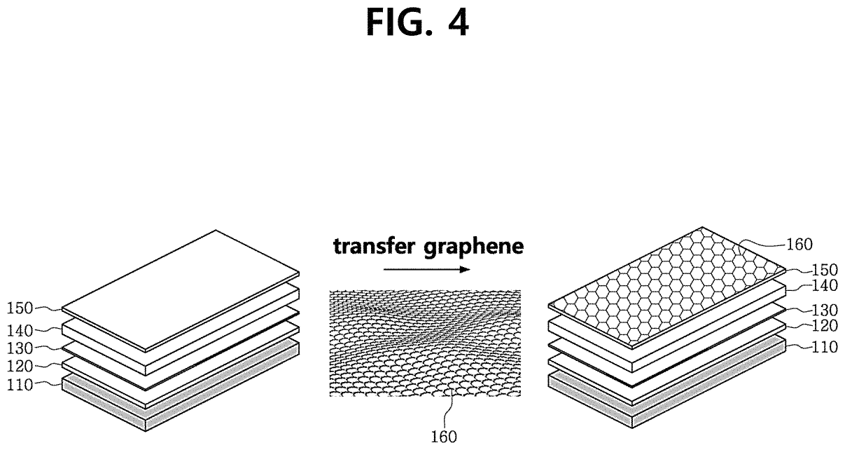

FIG. 4 is a schematic diagram illustrating a process of applying passivation according to an embodiment of the present disclosure.

The passivation layer 160 is formed on the hole transport layer 150. In an embodiment, the passivation layer 160 may be formed by transferring graphene onto the hole transport layer 150.

The graphene transfer may be performed by either PDMS (polydimethylsiloxane) based transfer process or PMMA (polymethyl methacrylate) based transfer process.

In an example, graphene grown on metal (for example, Ni or Cu) may be transferred onto the hole transport layer 150 by metal etching using PDMS or poly(methylmethacrylate) (PMMA) as a support layer.

However, the above-described graphene transfer method is provided for illustration only, but is not limited thereto.

As such, the solar cell 1 according to an embodiment has a non-inverted structure (N-I-P structure) including the graphene based passivation layer 160. Accordingly, the solar cell 1 may have high power conversion efficiency.

Further, the passivation layer 160 not only performs a passivation function of preventing moisture and thermochemical reaction, but also captures a different type of charge (i.e., hole) from the charge (i.e., electron) received in the electrode 120, functioning as an electrode (a hole electrode or a second electrode). Accordingly, it is possible to make the internal structure simpler and thereby reducing volume and size.

Additionally, in contrast to the existing metal based electrode, the solar cell 1 according to an embodiment is transparent, and may be thus used as a transparent solar cell.

### Second Embodiment

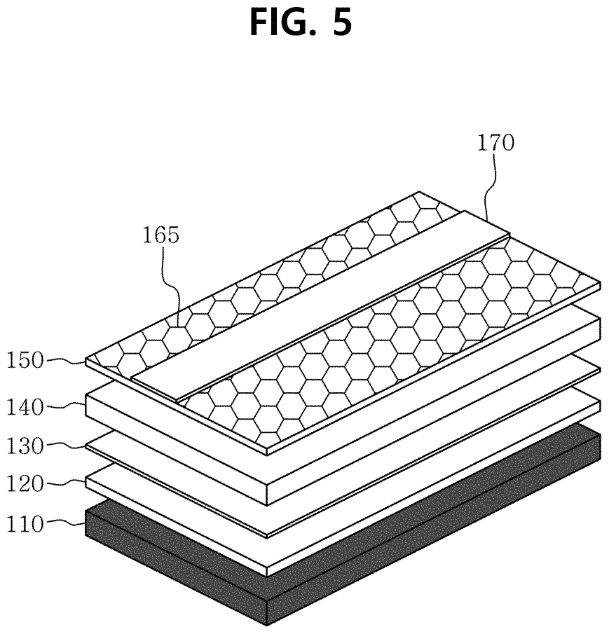

FIG. 5 is a diagram showing a device structure of a solar cell according to another embodiment of the present disclosure.

The halide perovskite based solar cell 1 according to another embodiment of the present disclosure is significantly similar to the halide perovskite based solar cell according to an embodiment as shown in FIG. 2, and difference(s) will be primarily described.

The solar cell 1 according to another embodiment includes an electrode 120 formed on a substrate 110, an electron transport layer 130 formed on the electrode 120, a photoactive layer 140 formed on the electron transport layer 130, a hole transport layer 150 formed on the photoactive layer 140, a passivation layer 165 formed on the hole transport layer 150, and an electrode 170 made of metal.

The working principle of the halide perovskite based solar cell 1 according to another embodiment is described for illustration as follows: the photoactive layer 140 made of a material including a halide perovskite compound generates an electron-hole pair therein when it receives sunlight. The electron generated in the photoactive layer 140 is transported to the electrode 120 through the electron transport layer 130. Additionally, the hole generated in the photoactive layer 140 is transported to the metal electrode 170 through the hole transport layer 150 and the passivation layer 165, and finally, is captured in metal of the metal electrode 170. As a result, the solar cell 1 generates an electric current.

The components 110 to 150 are the same as those of the solar cell 1 of an embodiment, and their detailed description is omitted herein.

The passivation layer 165 is a layer made of a 2D material, and provides passivation for the photoactive layer 140 against moisture and thermochemical stimuli. The passivation layer 165 is further configured to transport holes. That is, in contrast to the passivation layer 160 of an embodiment acting as an electrode, the passivation layer 165 of another embodiment is also used as another hole transport layer that is different from the hole transport layer 150.

In an embodiment, the passivation layer 165 is made of a material including graphene oxide.

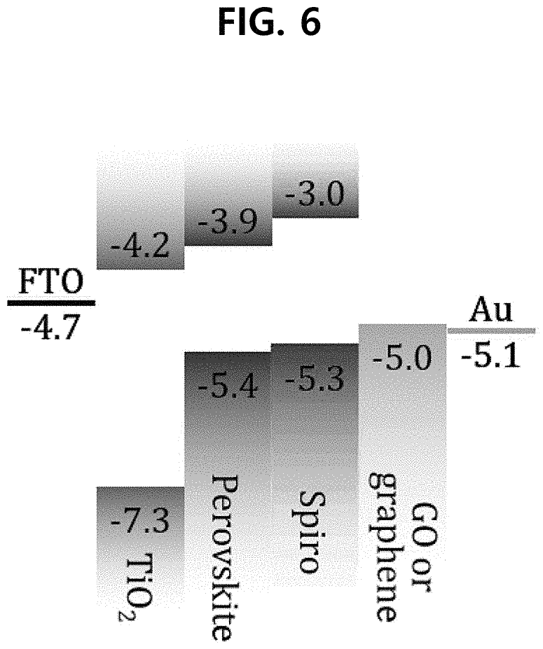

FIG. 6 is a diagram illustrating the band alignment of the solar cell of FIG. 5 according to another embodiment of the present disclosure.

The work function of graphene oxide may be tuned between about 3.7 eV and about 5.1 eV depending on its oxidation state. Accordingly, it is possible to achieve appropriate band alignment for almost any hole transport material (layer 150) mentioned in an embodiment, resulting in a wider range of solar cells 1 that can be manufactured.

In an embodiment, the passivation layer 165 may be formed based on the passivation layer 160 of FIG. 2. For example, when the passivation layer 160 of FIG. 2 is made of a material including graphene, the passivation layer 165 of FIG. 5 may be formed by performing oxidation treatment on graphene of FIG. 2.

For example, the passivation layer 165 may be formed by applying ozone cleaning or oxygen plasma treatment to graphene of FIG. 2.

The metal electrode 170 is formed on the passivation layer 165. In an embodiment, the metal electrode 170 is made of a material including gold (Au), but is not limited thereto, and the metal electrode 170 may be made of a variety of metal materials having a higher work function than the work function of graphene oxide. That is, a selection of metal may change depending on the work function of graphene oxide.

As such, the solar cell 1 according to another embodiment has the same forward structure as the solar cell 1 according to an embodiment, but uses a material having a higher energy level than the solar cell 1 according to an embodiment for the electrode, thereby achieving smoother charge movement.

### Third Embodiment

FIG. 7 is a diagram showing a device structure of a solar cell according to still another embodiment of the present disclosure.

Referring to FIG. 7, the solar cell 1 according to still another embodiment includes an electrode 260 formed on a substrate 210, a hole transport layer 250 formed on the electrode 260, a photoactive layer 240 formed on the hole transport layer 250, an electron transport layer 230 formed on the photoactive layer 240, and a passivation layer 220 formed on the electron transport layer 230.

The substrate 210 of FIG. 7 corresponds to the substrate 110 of FIG. 2, the photoactive layer 240 of FIG. 7 corresponds to the photoactive layer 140 of FIG. 2, and the passivation layer 220 of FIG. 7 corresponds to the passivation layer 160 of FIG. 2. Accordingly, with regard to the halide perovskite based solar cell 1 according to still another embodiment of the present disclosure, differences 260, 250, 230 from the halide perovskite based solar cell 1 according to an embodiment will be primarily described.

The working principle of the halide perovskite based solar cell 1 according to still another embodiment is described for illustration as follows: when sunlight is incident, photons are first absorbed in halide perovskite within the photoactive layer 240, and accordingly, electron transition (i.e., energy transition) occurs in halide perovskite from a ground state to an excited state. The photoactive layer 240 generates an electron-hole pair by the electron transition, and the generated hole is transported to the electrode 260 through the hole transport layer 250. On the other hand, the electron generated in the photoactive layer 240 is captured in the passivation layer 220 through the electron transport layer 230. As a result, the solar cell 1 can work.

The electrode (a hole electrode or a second electrode) 260 acts as a hole capture layer to receive and capture the hole in the photoactive layer 240 generated by sunlight through the hole transport layer 250.

The electrode 260 may be made of a material selected from the group consisting of indium tin oxide (ITO), fluorine doped tin oxide (FTO), tin oxide, zinc oxide and their combinations, but may not be limited thereto. In an embodiment, the electrode 260 is made of a material including ITO.

The electrode 260 is formed on the substrate 210. The electrode 260 may be formed on the substrate 210 by electroplating, sputtering and physical vapor deposition (PVD) such as electron beam evaporation, but is not limited thereto.

The hole transport layer 250 is configured to effectively transport the excited electron in the photoactive layer 240 to the electrode 260. In the solar cell, the photoactive layer 240 generally has a short hole diffusion lengths. Thus, the generated hole may not reach the electrode 260. As the hole transport layer 250 made of a material having a longer hole diffusion lengths may transport the hole to the electrode 260, the issue with short diffusion lengths may be mitigated.

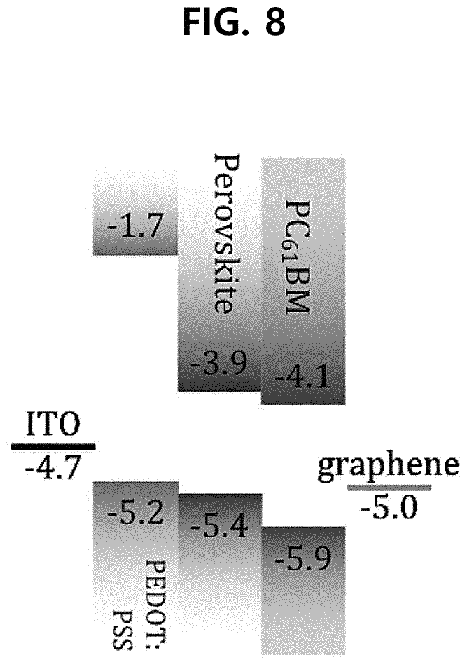

FIG. 8 is a diagram illustrating band alignment of the solar cell of FIG. 7 according to still another embodiment of the present disclosure.

The hole transport layer 250 is formed from a material having a higher valence band than the valence band of the perovskite solar cell. In an embodiment, the hole transport layer 250 may be made of p-type semiconducting oxides and/or organic materials including NiOx and PEDOT:PSS, but not limited to.

Referring back to FIG. 7, as described above, the photoactive layer 240 formed on the hole transport layer 250 includes a halide perovskite compound, and receives light (for example, sunlight) to generate electronic energy from light energy.

The electron transport layer 230 is made of a material that is efficient in transporting the electron. For example, the electron transport layer 230 is formed from a material having a lower conduction band than the conduction band of the perovskite solar cell.

In an embodiment, the electron transport layer 230 may be made of a material including TiO₂, ZnO, SnO₂, PC₆₁BM ([6,6] phenyl-C61-butyric acid methyl ester), but is not limited thereto.

The electron transport layer 230 is formed on the photoactive layer 240. The electron transport layer 230 may be formed on the photoactive layer 240 by a spin coating process or a thermal evaporation process, but is not limited thereto.

The passivation layer 220 is a layer formed on the electron transport layer 230 to prevent the photoactive layer 240 from decomposing and/or being damaged by heat or moisture. The passivation layer 220 may be made of a conductive 2D material that can prevent diffusion.

In an embodiment, the 2D material that forms the passivation layer 220 may include graphene. Accordingly, the passivation layer 220 of FIG. 7 performs a passivation function in the same way as the passivation layer 160 of FIG. 2. Additionally, similar to the passivation layer 160 of FIG. 2, the passivation layer 220 may further act as an electrode to capture a different type of charge from the charge captured in the electrode 260 that contacts the substrate 210.

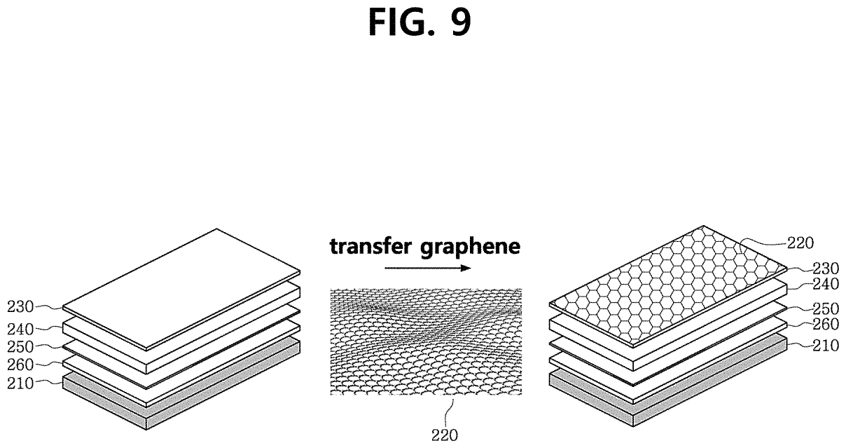

FIG. 9 is a schematic diagram illustrating a process of forming the passivation layer according to still another embodiment of the present disclosure.

The passivation layer 220 may be formed by transfer onto the electron transport layer 230 as shown in FIG. 9. The transfer of the passivation layer 220 was described with reference to FIG. 4, and the detailed description is omitted herein.

As such, the solar cell 1 according to still another embodiment has an inverted structure (P-I-N structure) including the graphene based passivation layer 220. Accordingly, this is an appealing structure for application in flexible devices.

Further, the passivation layer 220 not only serves as a passivation layer against moisture and thermochemical stimuli, but also captures a different type of charge (i.e., electron) from the charge (i.e., hole) received in the electrode 260, functioning as an electrode (an electron electrode or a first electrode). Accordingly, it is possible to make the internal structure simpler and thereby reducing volume and size.

Additionally, in contrast to the existing metal based electrode, the solar cell 1 according to still another embodiment is transparent and may be thus used as a transparent solar cell.

The present disclosure has been hereinabove described with reference to the embodiments shown in the drawings, but this is provided for illustration purposes only and those having ordinary skill in the corresponding field will understand that various modifications and variations may be made thereto. However, it should be noted that such modifications fall within the technical protection scope of the present disclosure. Accordingly, the true technical protection scope of the present disclosure shall be defined by the technical spirit of the appended claims.

What is claimed is:

1. An optoelectronic device, comprising:
a substrate;
a photoactive layer formed on the substrate to receive light and generate an electron-hole pair;
an electron transport layer and a hole transport layer formed on both surfaces of the photoactive layer;
a first electrode formed between the substrate and the photoactive layer; and
a passivation layer formed at an opposite side to the first electrode on the photoactive layer.

2. The optoelectronic device according to claim 1, wherein the passivation layer is made of a 2-dimensional material, and is configured to capture a type of charge of the hole-electron pair generated in the photoactive layer.

3. The optoelectronic device according to claim 1, comprising:
a first electrode formed on the substrate to capture an electron;
an electron transport layer formed on the first electrode;
a photoactive layer formed on the electron transport layer;
a hole transport layer formed on the photoactive layer; and
a passivation layer formed on the hole transport layer, wherein the passivation layer is made of a 2-dimensional material.

4. The optoelectronic device according to claim 3, wherein the passivation layer is made of a material including graphene.

5. The optoelectronic device according to claim 3, wherein the passivation layer is configured to capture the hole of the electron-hole pair generated in the photoactive layer through the hole transport layer.

6. The optoelectronic device according to claim 5, wherein the passivation layer can act as a second electrode of the optoelectronic device.

7. The optoelectronic device according to claim 1, comprising:
a first electrode formed on the substrate to capture an electron;
an electron transport layer formed on the first electrode;
a photoactive layer formed on the electron transport layer;
a hole transport layer formed on the photoactive layer;
a passivation layer formed on the hole transport layer and made of a 2-dimensional material; and
a third electrode formed on the passivation layer,
wherein the third electrode is made of metal.

8. The optoelectronic device according to claim 7, wherein the passivation layer is made of a material including graphene oxide.

9. The optoelectronic device according to claim 7, wherein the passivation layer can receive a hole generated in the photoactive layer through the hole transport layer, and transport the hole to the third electrode.

10. The optoelectronic device according to claim 7, wherein the metal of the third electrode has a higher work function than a work function of graphene oxide.

11. The optoelectronic device according to claim 7, wherein the graphene oxide of the passivation layer is formed by ozone cleaning or oxygen plasma treatment.

12. The optoelectronic device according to claim 1, wherein the photoactive layer is made of a material including a halide perovskite compound.

13. The optoelectronic device according to claim 1, wherein the first electrode is made of a material selected from the group consisting of indium tin oxide (ITO), fluorine doped tin oxide (FTO), tin oxide, zinc oxide and their combinations.

14. The optoelectronic device according to claim 3, wherein the hole transport layer is made of a material including spiro-MeoTAD.

15. The optoelectronic device according to claim 3, wherein the electron transport layer is made of a material selected from the group consisting of TiO₂, ZnO, SnO₂, PC₆₁BM and their combinations.

16. The optoelectronic device according to claim 1, comprising:
a second electrode formed on the substrate to capture a hole;
a hole transport layer formed on the second electrode;
a photoactive layer formed on the hole transport layer;
an electron transport layer formed on the photoactive layer; and
a passivation layer formed on the electron transport layer and made of a 2-dimensional material.

17. The optoelectronic device according to claim 16, wherein the passivation layer can act as a first electrode of the optoelectronic device to capture an electron of an electron-hole pair generated in the photoactive layer through the electron transport layer.

18. The optoelectronic device according to claim 16, wherein the hole transport layer is made of a material including NiOx or PEDOT:PSS.

19. The optoelectronic device according to claim 16, wherein the electron transport layer is made of a material including a fullerene derivative having a lower conduction band of the photoactive layer than a conduction band of a perovskite solar cell.

20. The optoelectronic device according to claim 19, wherein the electron transport layer is made of a material including PC₆₁BM ([6,6] phenyl-C61-butyric acid methyl ester).
